(19) United States
(12) Patent Application Publication
(10) Pub. No.: US 2025/0023534 A1
(43) Pub. Date: Jan. 16, 2025

(54) Fabrication Method for a Thin-Film Layer on a Substrate

(71) Applicant: QphoX B.V., Delft (NL)

(72) Inventors: Wilhelmus Johannes Duivestein, Delft (NL); Simon Groeblacher, Delft (NL); Bas Jorrit Hensen, Delft (NL); Frederick Mahmoud Hijazi, Delft (NL); Selim Scharmer, Delft (NL); Robert Hugh James Stockill, Delft (NL); Mathilde Flore Lemang, Delft (NL)

(21) Appl. No.: 18/713,339

(22) PCT Filed: Nov. 28, 2022
(86) PCT No.: PCT/EP2022/083541

§ 371 Date: May 24, 2024

(30) Foreign Application Priority Data
Nov. 26, 2021 (GB) 2117119.4
Jul. 11, 2022 (GB) 2210166.1

(51) Int. Cl. H03H 3/007; H03H 9/125; H03H 9/24

(52) U.S. Cl. CPC H03H 3/007; H03H 9/125; H03H 9/24

(57) ABSTRACT

A method for fabrication of a device from a material stack is disclosed. The material stack includes a first layer on a second layer. The method includes providing the material stack, creating a first mask on the surface of the first layer, patterning the first mask, a first etching step of the first layer to a pre-defined end point and thereby building regions of retained material, a second etching step of the first layer to remove remaining material from the first layer between the regions of retained material, creating a second mask on the surface of the second layer, patterning the second mask, etching the material of the second layer.

### CROSS-REFERENCE TO RELATED APPLICATIONS

This application is the United States national phase of International Patent Application No. PCT/EP2022/083541 filed Nov. 28, 2022, and claims priority to United Kingdom Patent Application No. 2117119.4 filed Nov. 26, 2021, and United Kingdom Patent Application No. 2210166.1 filed Jul. 11, 2022, the disclosures of each of which are hereby incorporated by reference in their entireties.

### BACKGROUND

### Field of the Invention

A method for creating a stack of patterned piezoelectric, dielectric, and metal films is disclosed.

This method includes patterning a thin piezoelectric film without damaging the underlying dielectric material. Furthermore, deposition of at least one of a metal, metal alloy or refractory metal is incorporated into the fabrication flow. The dielectric underneath the piezoelectric material is patterned and etched without damaging the piezoelectric material.

### Background of the Invention

Nanofabrication of stacks of thin films with contrasting physical properties presents the opportunity for new devices with diverse functionalities. At the same time, one of the primary limitations in the development of high-performance devices originates from defects (roughness) in the surface introduced in the fabrication process. To mitigate these effects, the surface properties (smoothness) need to be maintained during fabrication. This requirement is often challenging to satisfy when processing additional layers in the material stack, which may damage or introduce roughness to the underlying dielectric material. This document teaches a method for processing a piezoelectric layer while leaving an underlying dielectric layer in a pristine and smooth state. When subsequently processing the dielectric, the piezoelectric layer is also left in pristine condition. The deposition of a metal film that can cover both the dielectric and piezoelectric layers is also disclosed. The fabrication steps can be applied in different orders, as the fabrication steps are independent from one another.

Methods for processing stacks of thin films are known in the art. For example, Taiwanese patent application No TW 1233952 which describes a method for etching an oxide layer. The method is to form an oxide layer on a semiconductor substrate and form a photoresist layer on the oxide layer. Next, using the photoresist layer as a mask, a part of the oxide layer is removed by anisotropic etching, leaving a part of the oxide layer. The photoresist layer is used as a mask, and the residual oxide layer is removed by an isotropic etching method to reach the semiconductor substrate. The invention adopts anisotropic and isotropic in a two-stage etching method to etch the oxide layer under the photoresist. In this way, the silicon substrate is not damaged by the anisotropic etching. In addition, the lateral etching caused by isotropic etching can be reduced, so that the contact area between the photoresist layer and the oxide layer can be increased, and the adhesion between the photoresist layer and the oxide layer can be improved to avoid photoresist layer peeling.

US Patent Application No. US 2016/0079088 teaches methods for patterning a hardmask layer disposed on a metal layer, such as a copper layer, to form an interconnection structure in semiconductor devices. In one embodiment, a method of patterning the hardmask layer on the metal layer disposed on a substrate includes supplying a first etching gas mixture comprising a carbon-fluorine containing gas and a chlorine containing gas into a processing chamber to etch a portion of a hardmask layer disposed on a metal layer formed on a substrate, supplying a second etching gas mixture comprising a hydrocarbon gas into the processing chamber to clean the substrate, and supplying a third etching gas mixture comprising a carbon-fluorine containing gas to remove a remaining portion of the hardmask layer until a surface of the metal layer is exposed.

U.S. Pat. No. 6,204,190 teaches a method for producing an electronic device which comprises the steps of: depositing a thin film on a single crystal substrate or single crystal film, or on a triaxial or uniaxial orientation film; etching a portion of the thin film by a reactive ion etching so as to leave a remaining portion of the thin film behind; and removing the remaining thin film by a physical etching using an inert gas as the principal gas.

### SUMMARY OF THE INVENTION

A method for creating a stack of patterned piezoelectric, dielectric, and metal films and for fabrication of a device from a material stack is disclosed. The material stack comprises a first layer or piezo layer arranged on a second layer or dielectric layer. The second layer can be of any type of material which can have conductive or insulating properties. The second layer can be of a dielectric or semiconducting material. This method includes patterning a thin piezoelectric film without damaging the underlying dielectric material. Furthermore, a metal deposition is incorporated into the fabrication flow. The dielectric underneath the piezoelectric material is patterned and etched without damaging the piezoelectric material.

The method comprises providing the material stack, creating a first mask on the surface of the first layer, patterning the first mask, a first etching step of the first layer to a pre-defined end point and thereby building regions of retained material, and a second etching step of the first layer to remove remaining material from the first layer between the regions of retained material, creating a second mask on the surface of the second layer, patterning the second mask, anisotropic etching of the material of the second layer. The regions of retained material can later sit atop material of a free-standing or suspended structure or region. On one aspect, this free-standing structure may be a beam-like structure.

The step of etching can comprise anisotropic and/or isotropic etching. The etching can be conducted to undercut and thereby form the retained regions of retained material of the first and second layer to create the suspended structure. The etching can also be conducted to undercut a sacrificial layer to obtain the retained regions of the first layer and the second layer. The first layer and the second layer form the free-standing structure.

The step of providing the material stack can comprise growing a region of the first layer on the second layer.

The step of providing the material stack can alternatively comprise transferring a region of the first layer to the second layer, wherein the region of the first layer is located on a substrate, attaching the region of the first layer, and removing the substrate. The region of the first layer does not necessarily need to be located on a substrate, i.e., in the case of a stamping process. The step of removing the substrate can also be optional, i.e., in the case of a stamping process.

The steps of creating a mask can comprise at least one of spinning a resist, applying hydrogen silsesquioxane by a spin on glass process, and/or applying silicon nitride and/or any kind of material by a deposition, growth, or sputtering process.

The method can further comprise depositing a conductive layer on the device and removing unwanted conductive material from the conductive layer through at least one of lift-off or etching to form conductive regions or electrodes, electrical waveguides, and/or resonators. The method can further comprise spinning a third resist on the dielectric material and patterning the third resist.

The conductive layer can comprise a superconducting material.

The first layer can be a layer of piezoelectric material and/or the second layer can be a layer of semiconductor material, dielectric material, or doped dielectric material.

The method can further comprise an additional sacrificial layer located between the second layer and a handle layer.

The method can further comprise thermal annealing of the material stack.

A device is further disclosed. The device comprises a piezoelectric layer on a dielectric layer, wherein the device has a plurality of structured regions of the first layer and structured regions of the second layer.

The device can comprise a sacrificial layer which is located between the dielectric layer and a handle layer, wherein the sacrificial layer is not present under the structured regions of the second layer.

The first layer can be a piezoelectric material and the second layer can be a semiconductor material.

Ones of the plurality of the structured regions of the second layer can form a free-standing or suspended structure which may be a membrane or beam-like structure.

The device can further comprise a conductive layer on the first layer and/or the second layer.

The device can be used for microwave-to-optical transduction (transduction between microwave and optical photons).

The fabrication methods discussed here have numerous applications, such as in the areas of integrated microwave and nanophotonics devices in which a structured piezoelectric material is used to actuate a mechanical resonator.

A particular process flow is described as it relates to the fabrication of conversion devices for microwave-to-optical transduction. In this respect, microwave-to-optical transduction is coherent bidirectional wavelength (frequency) conversion between radiation in the microwave domain and the optical domain. The microwave domain relates to electromagnetic radiation with frequencies between 300 MHz-300 GHz (for example 3-10 GHz) and the optical domain corresponds to electromagnetic radiation with wavelengths (frequencies) between 300 nm-1 mm (300 GHz-999 THZ), in one aspect 1300 nm-1700 nm (176-230 THz). In general, the conversion devices in this document are aimed at converting signals with single or low photon numbers, i.e., between zero and 1000 photons.

The conversion devices are typically comprised of coupled nanoscale cavity-optomechanical and piezo-electric circuits, but this is not limiting of the invention. The optomechanical cavity supports co-localized infrared photons and microwave phonons and is combined with photonic and phononic waveguides.

However, it will be appreciated that these same methods may be employed for creating a much broader class of devices. In general, the approach can be employed to any stack of layers of distinct materials, where the top layer (subsequently referred to as “piezoelectric-layer”) should be patterned while keeping the bottom layer's (“dielectric layer”) surface intact and subsequently patterning the bottom layer without etching the top layer. In addition, a metal deposition can be included in the process.

### BRIEF DESCRIPTION OF THE DRAWINGS

The terms FIG., FIGS., Figure, and Figures are used interchangeably in the specification to refer to the corresponding figures in the drawings.

FIG. 1 shows an exemplary device made according to one aspect of the invention.

FIG. 2A shows a cross-sectional view of the material stack and fabrication process flow according to a first aspect.

FIG. 2B shows a cross-sectional view of the material stack and fabrication process flow according to a second aspect.

FIG. 2C shows a cross-sectional view of the material stack and fabrication process flow according to a third aspect.

FIG. 3 shows a flow diagram illustrating the fabrication process according to a first aspect.

FIG. 4 shows a flow diagram illustrating the fabrication process according to a second aspect.

FIG. 5 shows a flow diagram illustrating the fabrication process according to a third aspect.

### DETAILED DESCRIPTION

The invention will now be described on the basis of the disclosure and drawings. It will be understood that the embodiments and aspects of the invention described herein are only examples and do not limit the protective scope in any way. It will be understood that features of one aspect or embodiment of the invention can be combined with a feature of a different aspect or aspects and/or embodiments of the invention.

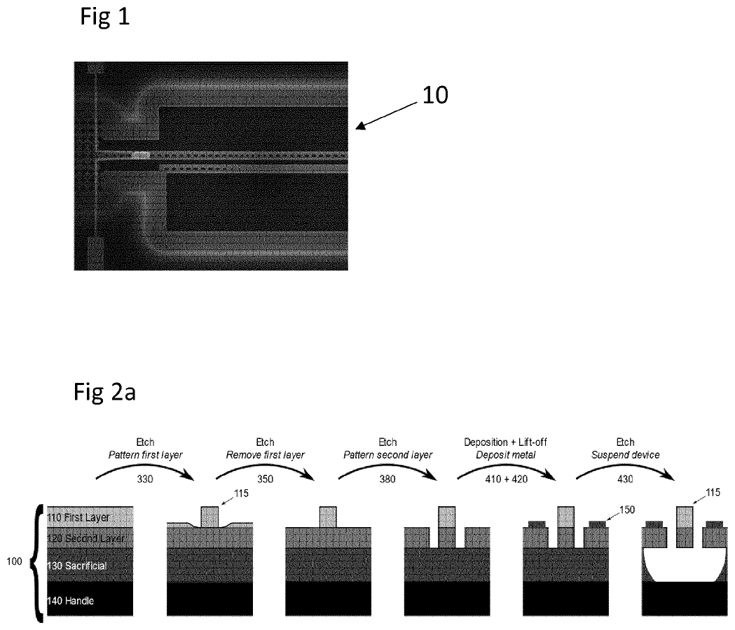

FIG. 1 shows a top-down view of an exemplary device 10 made according to the process described in this document. The device 10 can perform wavelength conversion between microwave signals and optical signals. The device is made from a one-dimensional optomechanical crystal (which is a periodic structure in only one dimension) and is implemented in the form of a periodically patterned free-standing or suspended structure, such as but not limited to, a beam-like structure. The device is made from a dielectric material, such as but not limited to silicon, silicon nitride, silicon carbide, gallium arsenide, and/or gallium phosphide. The device 10 can also be implemented from a two-dimensional opto-mechanical crystal. A defect in the patterned nanobeam allows for localization of the acoustic resonances and optical resonances to enhance opto-mechanical coupling.

The suspended structure (or optomechanical crystal) is suspended by removing a sacrificial layer below the dielectric material using isotropic etching to allow for mechanical vibration of the suspending structure. The isotropic etching undercuts the dielectric material.

A piezoelectric actuator in the form of a first layer or piezoelectric layer is implemented on top of the suspended opto-mechanical crystal resonator (second layer or dielectric layer) to transduce between a microwave signal and a mechanical motion of the optomechanical crystal. Examples of materials for the first layer or piezoelectric layer include, but are not limited to, lithium niobate, lithium tantalate, barium tantalate, aluminium nitride, gallium arsenide and/or gallium phosphide.

Finally, a pair of conductive electrodes made, for example, of gold is deposited on top of both the piezoelectric layer and the dielectric layer to interface the piezoelectric material with electrical signals. The electrodes can be further patterned to form a resonator to localize microwave-frequency photons. It will be appreciated that the conductive electrodes may be fabricated from either a normal metal or superconducting material, such as alloys of molybdenum rhenium, niobium, niobium titanium, niobium titanium nitride, titanium nitride, tantalum, and/or aluminium. It would also be possible to use another layer of a semiconductor.

The deposition and structuring of piezoelectric materials on a dielectric substrate may be accomplished through a variety of methods which depend on the specific material combination considered. For applications involving photonics, it is generally preferred to first pattern a mask on the dielectric layer, after which the piezoelectric layer is then grown and selectively removed through lift-off. However, such methods restrict the range of use to materials which can be grown compatibly.

A more general method is to deposit one of the materials on top of the other on a wafer scale, which can allow for the creation of hybrid material platforms that are otherwise incompatible with one another. Non-limiting examples include lanthanides on silicon or on silicon dioxide. In this case, a piezoelectric layer must then be selectively removed (etched) from the surface to define the piezo-device geometry. Various chemical and physical etch processes are available that are suitable for a small range of specific materials. Here we present a general method for structuring the piezoelectric material based on ion bombardment which may be used for any combination of materials.

### General Methods

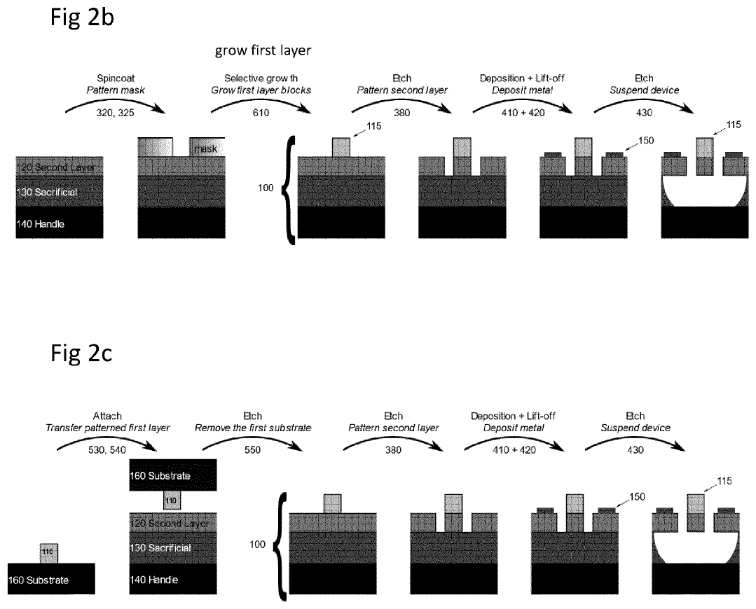

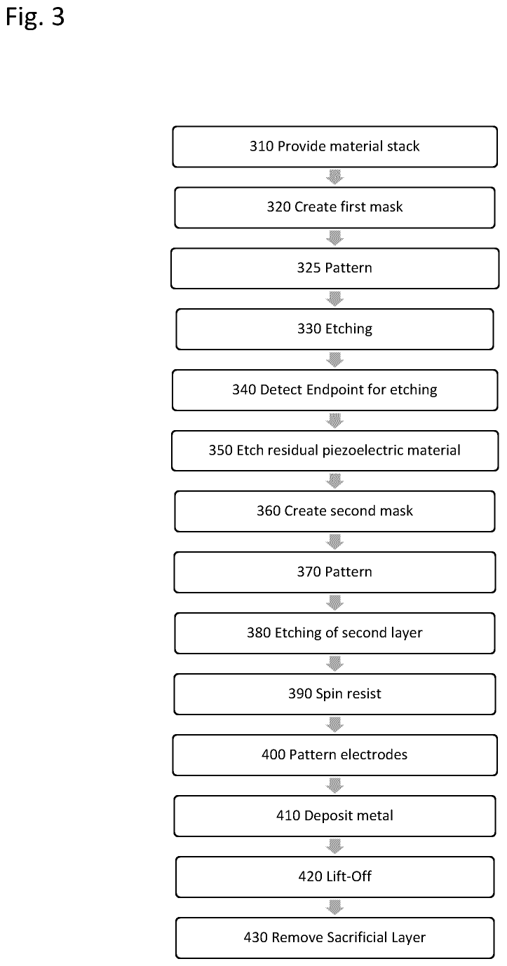

A generalized material stack 100 according to a first aspect for forming the device is comprised from the following elements: a first layer or piezoelectric layer 110, a second layer or dielectric layer 120, a sacrificial layer 130 and a handle layer 140 as shown in FIG. 2Aa. A flow diagram illustrating the flow of the fabrication according to the first aspect is shown in FIG. 3. As noted above, the piezoelectric layer 110 is provided, by e.g., deposition or bonding, on the dielectric layer 120 which is in turn deposited on the sacrificial layer 130 (if included) and the handle layer 140. As noted above the material stack 100 is formed or provided in step 310, for example, by wafer bonding methods, such as wafer scale deposition methods. The step 310 comprises the steps of creating 320 a first mask, patterning 325 the first mask, etching 330, and etching 350. The step 310 can further comprise the step of detecting 340 an endpoint for etching 330.

It will be appreciated that during the creation of the material stack 100 a conductive layer 150 may then be added to either the piezoelectric layer 110, the dielectric layer 120, or combination thereof to provide electrodes 150 for driving or being driven by the piezoelectric layer 110.

The piezoelectric layer 110 is patterned by creating a first mask in step 320 on a top surface of the material stack 100. The first mask can be created by spinning a resist on the top surface of the material stack 100 to create a resist layer. A pattern is transferred using a lithography step 325 which produces a pattern in the first mask (i.e., in the resist layer) over those regions 115 of the piezoelectric layer 110 which should be retained. These retained regions 115 will later sit atop of the free-standing or suspended structure. As noted above, the suspended structure region can (but need not) be a beam-like structure.

In an alternative aspect, the first mask can alternatively be created on the top surface of the material stack 100 by spinning hydrogen silsesquioxane or by applying silicon nitride by a sputtering process to the top surface of the material stack 100. It will be appreciated that the invention is not limited to these methods for creation of the mask and that other methods may be used.

Anisotropic etching, for instance ion bombardment (ion-milling), is used to remove in step 330 the unprotected regions of the piezoelectric layer 110 to form the retained regions 115. The physical etching mechanism employed allows this technique to be used for any material. This etching process should not damage the smooth surface quality of the material in the dielectric layer 120 below. Due to unevenness in etching and of the material throughout the chip or wafer, the etching must be stopped before all the piezoelectric material is removed from the dielectric layer 120, in order not to damage the underlying surface of the dielectric layer 120. Several techniques can be employed to detect 340 the optimal endpoint for the etching process, minimizing the remaining piezoelectric material, including calibrated timing and end-point detection, for instance based on in-situ secondary ion mass spectroscopy. The process is terminated such that a thin layer of piezoelectric material remains on the surface of the dielectric layer 120 which subsequently needs to be removed.

A wet-etch process or a gas-etch process is employed to selectively remove the thin residual layer of the piezoelectric material. By removing the final layer of the piezoelectric material with this etching process 350, the surface quality of the dielectric layer 120 underneath will remain smooth, ensuring good properties.

To pattern the dielectric layer 120, a second mask is created in step 360 and patterned in step 370 using lithography. As noted above in connection with the first mask, the second mask can be created by a number of methods, such as spinning a resist on the dielectric layer 120 or alternatively by applying hydrogen silsesquioxane by a spin on glass process or by applying silicon nitride by a sputtering process to the top surface of the dielectric layer 120. The dielectric layer 120 may be structured in step 380 using a dry-etch process, such as cryogenic SF₆/O₂ or HBr reactive ion etching, or any other selective anisotropic etching process. Etching 380 the dielectric layer 120 further structures the regions which will later be suspended. These regions may form a beam-like structure. Several techniques can be employed to detect the optimal endpoint for the step etching 380, minimizing the remaining piezoelectric material, including calibrated timing and end-point detection, for instance based on in-situ secondary ion mass spectroscopy.

For the next step to produce the conductive patterned layer, resist is spun in step 390 to produce a further resist layer and patterned in step 400 using lithography to define a conductive layer for the electrodes. The conductor may be deposited in step 410 on the sample using various approaches, such as evaporation or sputtering techniques. The desired pattern of the conductor can be obtained by removing the metal that is deposited in a process that is called lift-off in step 420, which is non-destructive to the high-quality surface of the dielectric layer 120. Alternatively, etching can be used instead of lift-off.

Alternatively, metal, metal alloys, or metal compounds can be deposited on the sample to create the conductive patterned layer. The metal, metal alloy or metal compound can react and form a thin layer of an intermetallic compound. This reaction can be accompanied by annealing to promote the reaction or the formation. A selective etching can be conducted to remove the metal or the metal alloy that has not reacted. The thickness of the thin layer of intermetallic compound can be controlled through the amount of thermal energy supplied during annealing.

Finally, the sacrificial layer underneath the dielectric is selectively removed in step 430 using a wet or dry etch, without damaging the piezoelectric, dielectric, and conductor layers using isotropic etching. The removal of the sacrificial layer undercuts the dielectric layer and thereby creates a structure which is free-standing or suspended and acts in this aspect as the mechanical resonator.

In between the above-mentioned steps, several cleaning steps may be employed to remove residual resist and prepare the layers for the next step. The cleaning steps can, for example, comprise etching, milling, encapsulating, protecting, or ultrasonic cleaning.

It will be appreciated that the order of the materials and steps (piezoelectric, dielectric, metal) can be exchanged, without significant impact on the individual process flow.

In a further aspect, a thermal annealing step may be applied to the device 100 one or more times before and during the method. Specifically, the thermal anneal step may be applied before creation of the mask or spinning of the resist in step 320, after anisotropic etching of the piezoelectric layer 110 in step 330, after etching of the residual piezoelectric material in step 350, after anisotropic etching of the dielectric layer in step 380, or after deposition of the metal layer in step 410. The annealing temperature may be between 298K and 1500K. The annealing atmosphere may include argon, oxygen, forming gas (hydrogen/nitrogen mixture), or in a vacuum. The annealing time may range between less than a millisecond and up to 72 hours, depending on the annealing technology. Direct Surface Annealing (=Dynamic surface annealing) or Laser surface annealing can be used as annealing technologies.

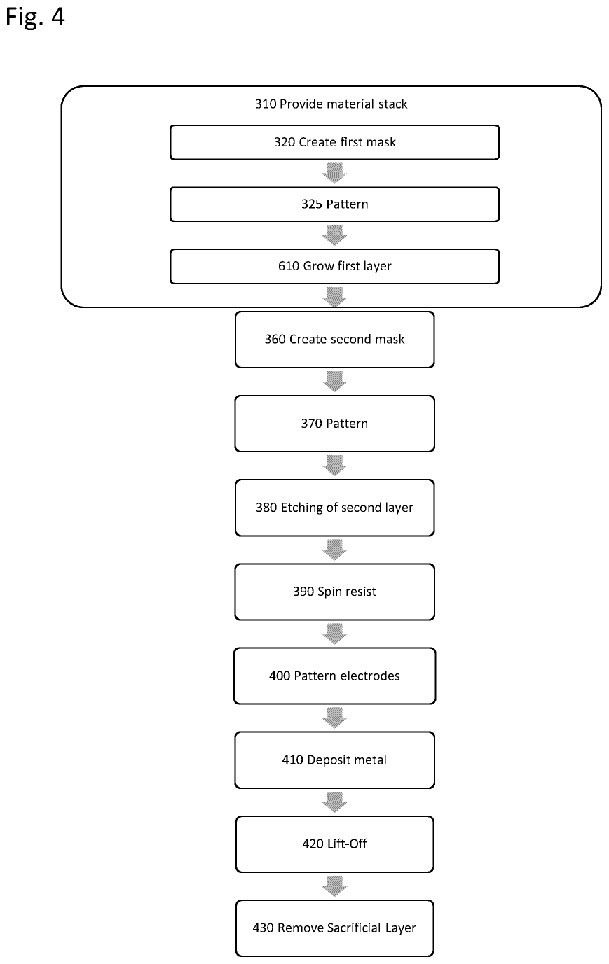

A generalized material stack 100 according to a second aspect for forming the device is comprised of the following elements: retained regions 115 of a piezoelectric layer or first layer 110, a dielectric layer or second layer 120, a sacrificial layer 130 and a handle layer 140 as shown in FIG. 2B. A flow diagram illustrating the flow of the fabrication according to the second aspect is shown in FIG. 4. The flow of the fabrication according to the second aspect differs from the flow of fabrication according to the first aspect only in the step of providing 310 the material stack 100. The remaining steps 360-430 are the same as for the first aspect and will therefore not be described.

The step 310 comprises the steps of creating 320 a first mask, patterning 325 the first mask, and selectively growing 610 the retained regions 115 of the first layer on the second layer 120. The selectively grown piezoelectric material can be crystalline or amorphous. Crystallization annealing can further be applied to the selectively grown piezoelectric material.

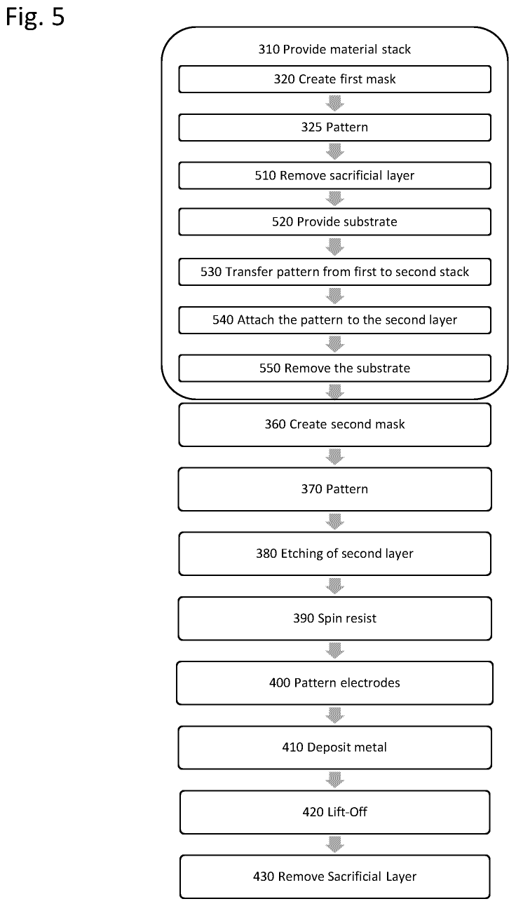

A generalized material stack 100 according to a third aspect for forming the device is comprised from the following elements: retained regions 115 of a piezoelectric layer or first layer 110, a dielectric layer or second layer 120, a sacrificial layer 130 and a handle layer 140 as shown in FIG. 2C. A flow diagram illustrating the flow of the fabrication according to the third aspect is shown in FIG. 5. The flow of the fabrication according to the third aspect differs from the flow of fabrication according to the first aspect only in the step of providing 310 the material stack 100. The remaining steps 360-430 are the same as for the first aspect and will therefore not be described. The step 310 comprises the steps of creating 320 a first mask, patterning 325 the first mask, removing 510 at least part of a sacrificial layer, providing 520 a substrate 160 with retained regions 115 of a piezoelectric material, transferring 530 the retained regions 115 which are located on the substrate 160 to the second layer 120, attaching or bonding 540 the retained regions 115 of the piezoelectric material to the second layer 120 and removing 550 the substrate 160. The attaching 540 can be conducted, for example, by annealing.

### EXAMPLE

For the device shown in FIG. 1, the starting material stack 100 comprises a wafer of thin-film crystalline LiNbO3 (lithium-niobate or LN) bonded to a Silicon-on-Insulator (SOI) wafer. The material stack 100 has a typically a thickness between 50 μm and 5000 μm, for example 700 μm. The lithium-niobate layer is, for example, between 50 and 1000 nm, e.g., 300 nm. The silicon layer in the SOI wafer is, for example, between 20 nm and 1000 nm, e.g., 250 nm. The silicon dioxide layer is typically between 500 nm and 10 μm, e.g., 3 μm. This material is commercially available and provided on a silicon handle layer 140.

To pattern the lithium-niobate piezoelectric layer 110 a first mask is created, or a resist is spun on top of the material stack 100 in step 320 and patterned in step 325 using electron beam lithography. As one example, CSAR 62 (AR-P 6200) from Allresist GmbH, Germany, is used as the resist, but this is not limiting of the invention. It is also possible to use photolithography with resists, such as SU8 from Microchem Corp.

Ion (Ar+) milling is used to remove the lithium-niobate in step 330 while the patterned resist prevents removal in some places. End point detection in step 340 based on secondary ion mass spectroscopy is used to determine when most, but not all, of the LN piezoelectric layer 110 is removed from the patterned openings.

The resist is removed from the sample, followed by a wet etch in step 350 to remove the remaining layer of lithium niobate between the regions of retained lithium niobate. The wet etch is a mixture of H2O:H2O2:NH₄OH, in the ratios 1-2:1-4:1-4. an elevated temperature, e.g., 50° C. to 80° C., to increase the etch rate. By removing the remaining layer of the lithium niobate with a wet etching process the silicon dielectric layer 120 underneath will remain smooth.

To pattern the silicon dielectric layer 120, a second mask is created in step 360 and patterned in step 370 using electron-beam lithography. The second mask can be created by spinning a resist on the dielectric layer 120 or alternatively by applying hydrogen silsesquioxane by a spin on glass process or by applying silicon nitride by a sputtering process to the top surface of the dielectric layer 120. The silicon is dry etched in step 380 using a fluorine-based chemistry (such as C4F8/SF6 or SF6/O2 at cryogenic temperatures) or using Cl or HBr chemistry. After patterning the silicon, the resist is removed, and the silicon is cleaned using an organic clean to remove any organic residues on the surface of the silicon.

After cleaning, further resist is spun in step 390 and patterned in step 400 using electron-beam lithography. Metal for the conductive layer 150 can be deposited in step 410 on the sample using evaporation or sputtering techniques. The desired pattern of the metal can be obtained by removing the metal by the lift-off process in step 420. After lift-off, the sample can again be cleaned.

Finally, the silicon dioxide sacrificial layer 130 underneath the silicon dielectric layer 120 is removed using the wet etch in step 430, without damaging the lithium-niobate, silicon, and deposited metal. This removal of the silicon dioxide sacrificial layer 130 undercuts the silicon dielectric layer 120. Typically, this wet etch step 430 would be performed on a sample of silicon and silicon oxide using a diluted hydrofluoric acid. An alternative to diluted hydrofluoric acid is a buffered oxide etch consisting of water, hydrofluoric acid, and ammonium fluoride in various concentrations. A buffered oxide etches with a low concentration of hydrofluoric acid in comparison to ammonium fluoride and will not etch the lithium-niobate but will introduce etching in the silicon dielectric layer 120. Therefore, a mixture of diluted hydrofluoric acid and a buffered oxide etch is used for the etching of silicon oxide. This wet etch does not etch the lithium-niobate piezoelectric layer 110 or the conductive layer 150 but etches the sacrificial layer 130 fast enough to undercut the silicon dielectric layer 120 but prevent etching of the silicon dielectric layer 120 and the handle layer 140. The step 430 can alternatively comprise hydrogen fluoride vapor etching or critical point drying.

### REFERENCE NUMERALS

10 Device
100 Stack
110 First layer
120 Second layer
130 Sacrificial Layer
140 Handle Layer
150 Conductive Layer

1. A method for fabrication of a device from a material stack, the material stack
comprising a first layer arranged on a second layer, the method comprising:
providing the material stack;
creating a first mask on the surface of the first layer;
patterning the first mask;
a first etching step of the first layer to a pre-defined end point and thereby building regions of retained material;
a second etching step of the first layer to remove remaining material from the first layer between the regions of retained material;
creating a second mask on the surface of the second layer;
patterning the second mask; and
etching of the material of the second layer without removing the regions of retained material of the first layer.

2. The method according to claim 1, wherein the first etching step comprises isotropic or anisotropic etching and the first etching step is conducted to undercut and thereby form retained regions of the first layer on retained material of the second layer to create a suspended structure.

3. The method according to claim 1, wherein the step of providing the material stack comprises growing a region of the first layer on the second layer.

4. The method according to claim 1, wherein the step of providing the material stack comprises:
transferring a region of the first layer to the second layer, wherein the region of the first layer is located on a substrate;
attaching the region of the first layer to the second layer; and
removing the substrate.

5. The method according to claim 1, wherein the step(s) of creating a first mask and/or creating a second mask independently comprise at least one of spinning a resist, applying hydrogen silsesquioxane by a spin on glass process, and/or applying silicon nitride by a sputtering process.

6. The method of claim 1, further comprising depositing a conductive layer on the device and removing unwanted conductive material from the conductive layer through at least one of lift-off and/or etching to form conductive regions.

7. The method according to claim 6, wherein the conductive layer comprises a superconducting material.

8. The method of claim 1, wherein the first layer is a layer of piezoelectric material and/or the second layer is a layer of semiconductor material or dielectric material.

9. The method of claim 1, further comprising an additional sacrificial layer located between the second layer and a handle layer.

10. The method of claim 1, further comprising removing the sacrificial layer under the regions of retained material.

11. The method of claim 1, further comprising thermal annealing of the material stack.

12. A device fabricated according to claim 1, the device comprising a first layer on a second layer, wherein the device has a plurality of retained regions of the first layer and structured regions of the second layer.

13. The device of claim 12, further comprising a sacrificial layer between the second layer and a handle layer, wherein the sacrificial layer is not present under the structured regions of the second layer.

14. The device of claim 12, wherein the first layer is a piezoelectric material, and the second layer is a layer of semiconductor material or dielectric material.

15. The device of claim 12, wherein region(s) of the plurality of structured regions of the second layer form a suspended structure.

16. The device of claim 12, further comprising a conductive layer on the first layer and/or the second layer.

17. A microwave-to-optical transduction device comprising the device of claim 12.
